(19) United States
(12) Patent Application Publication
(10) Pub. No.: US 2024/0162223 A1
(43) Pub. Date: May 16, 2024

(54) SEMICONDUCTOR DEVICE

(71) Applicant: Mitsubishi Electric Corporation, Tokyo (JP)

(72) Inventors: Koichi NISHI, Tokyo (JP); Kazuya KONISHI, Tokyo (JP)

(73) Assignee: Mitsubishi Electric Corporation, Tokyo (JP)

(21) Appl. No.: 18/329,853

(22) Filed: Jun. 6, 2023

(30) Foreign Application Priority Data
Nov. 15, 2022 (JP) 2022-182542

(51) Int. Cl. H01L 27/06; H01L 29/40; H01L 29/739; H01L 29/861

(52) U.S. Cl. CPC H01L 27/0664; H01L 29/407; H01L 29/7397; H01L 29/8613

(57) ABSTRACT

An IGBT region and a diode region are provided on a semiconductor substrate. The IGBT region includes a plurality of active trenches penetrating through the base layer and the emitter layer from the first principal surface, a gate electrode provided inside the active trenches via a gate insulating film, and an implanted electrode provided inside the active trenches via the gate insulating film and positioned on the second principal surface side of the gate electrode. The diode region includes an anode layer of the second conductive type provided on the first principal surface side of the drift layer, a plurality of diode trenches provided from the first principal surface to the anode layer, and a diode electrode provided inside the diode trenches via a diode insulating film. A depth of the anode layer is deeper than a depth of the diode trenches.

### BACKGROUND OF THE INVENTION

### Field

The present disclosure relates to a semiconductor device.

### Background

An RC-IGBT having a split gate structure has been proposed (see, for example, Patent Literature 1).

### CITATION LIST

### Patent Literature

Patent Literature 1: JP 2017-147431 A

### SUMMARY

### Technical Problem

In related art, a carrier accumulation layer is formed in a diode region, and a trench bottom portion of the diode region is in contact with a drift layer. Thus, an electric field is likely to concentrate on the trench bottom portion, which makes a reverse recovery safe operation area (RRSOA) narrow and causes a problem that breakage is likely to occur upon recovery operation.

The present disclosure has been made to solve the problem as described above, and an object of the present disclosure is to provide a semiconductor device capable of improving an RRSOA in an RC-IGBT having a split gate structure.

### Solution to Problem

A semiconductor device according to the present disclosure includes: a semiconductor substrate including a drift layer of a first conductive type between a first principal surface and a second principal surface opposed to each other; an IGBT region and a diode region provided on the semiconductor substrate; and an emitter electrode provided on the first principal surface of the semiconductor substrate, wherein the IGBT region includes a carrier accumulation layer of the first conductive type provided on the first principal surface side of the drift layer, a base layer of a second conductive type provided on the first principal surface side of the carrier accumulation layer, an emitter layer of the first conductive type and a contact layer of the second conductive type provided on the first principal surface side of the base layer, a plurality of active trenches penetrating through the base layer and the emitter layer from the first principal surface, a gate electrode provided inside the active trenches via a gate insulating film, an implanted electrode provided inside the active trenches via the gate insulating film and positioned on the second principal surface side of the gate electrode, and a collector layer of the second conductive type provided on the second principal surface side of the drift layer, wherein the diode region includes an anode layer of the second conductive type provided on the first principal surface side of the drift layer, a plurality of diode trenches provided from the first principal surface to the anode layer, a diode electrode provided inside the diode trenches via a diode insulating film, and a cathode layer of the first conductive type provided on the second principal surface side of the drift layer, wherein a depth of the anode layer is deeper than a depth of the diode trenches.

### Advantageous Effects of Invention

In the present disclosure, a depth of the anode layer is deeper than a depth of the diode trench in the diode region. By covering and protecting bottom portion of the diode trench with the anode layer, the electric field in the bottom portion of the diode trench can be relaxed. As a result of this, it is possible to improve the RRSOA in the RC-IGBT having a split gate structure.

### BRIEF DESCRIPTION OF DRAWINGS

FIG. 1 is a cross-sectional view illustrating a semiconductor device according to a first embodiment.

FIG. 2 is a cross-sectional view along I-II in FIG. 1.

FIG. 3 is a cross-sectional view illustrating a semiconductor device according to a second embodiment.

FIG. 4 is a cross-sectional view illustrating a semiconductor device according to a third embodiment.

FIG. 5 is a cross-sectional view illustrating a semiconductor device according to a fourth embodiment.

FIG. 6 is a cross-sectional view illustrating a semiconductor device according to a fifth embodiment.

FIG. 7 is a cross-sectional view illustrating a semiconductor device according to a sixth embodiment.

FIG. 8 is a cross-sectional view illustrating a semiconductor device according to a seventh embodiment.

FIG. 9 is a plan view illustrating a semiconductor device according to an eighth embodiment.

FIG. 10 is a cross-sectional view along I-II in FIG. 9.

FIG. 11 is a cross-sectional view illustrating a semiconductor device according to a ninth embodiment.

FIG. 12 is a cross-sectional view illustrating a semiconductor device according to a tenth embodiment.

FIG. 13 is a cross-sectional view illustrating a semiconductor device according to an eleventh embodiment.

FIG. 14 is a cross-sectional view illustrating a semiconductor device according to a twelfth embodiment.

FIG. 15 is a cross-sectional view illustrating a semiconductor device according to a thirteenth embodiment.

### DESCRIPTION OF EMBODIMENTS

A semiconductor device according to the embodiments of the present disclosure will be described with reference to the drawings. The same components will be denoted by the same symbols, and the repeated description thereof may be omitted.

### First Embodiment

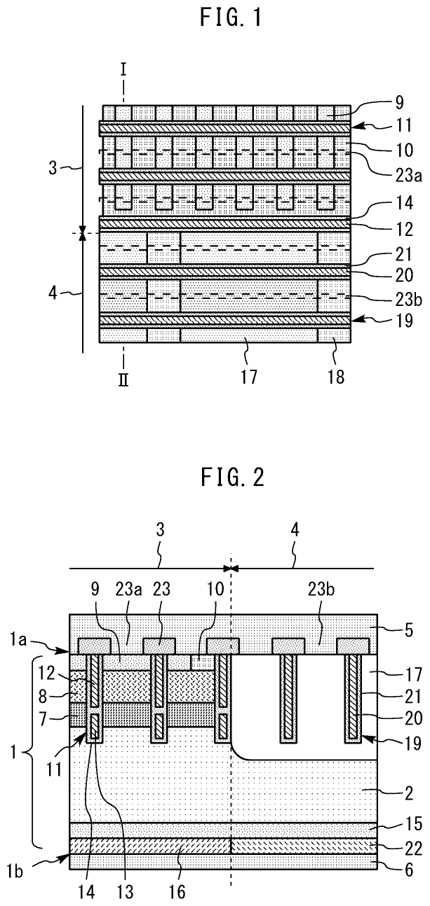

FIG. 1 is a cross-sectional view illustrating a semiconductor device according to a first embodiment. FIG. 2 is a cross-sectional view along I-II in FIG. 1. The semiconductor device is an RC-IGBT having a split gate structure. A semiconductor substrate 1 includes a drift layer 2 of a first conductive type between a first principal surface 1a and a second principal surface 1b opposed to each other. Note that, for example, the first conductive type is an n type, and a second conductive type is a p type.

An IGBT region 3, a diode region 4 and an implanted electrode pull-up region (not illustrated) are provided on the semiconductor substrate 1. An emitter electrode 5 is provided on the first principal surface 1a of the semiconductor substrate 1. A collector electrode 6 is provided on the second principal surface 1b of the semiconductor substrate 1. Note that a barrier metal layer may be provided between the semiconductor substrate 1 and the emitter electrode 5. A front metal may be provided on the emitter electrode 5 through plating, or the like.

In the IGBT region 3, a carrier accumulation layer 7 of the first conductive type is provided on the first principal surface 1a side of the drift layer 2. Impurity concentration of the carrier accumulation layer 7 is higher than that of the drift layer 2. A base layer 8 of the second conductive type is provided on the first principal surface 1a side of the carrier accumulation layer 7. An emitter layer 9 of the first conductive type and a contact layer 10 of the second conductive type are provided on the first principal surface 1a side of the base layer 8.

A plurality of active trenches 11 are provided while penetrating through the emitter layer 9, the base layer 8 and the carrier accumulation layer 7 from the first principal surface 1a of the semiconductor substrate 1. A gate electrode 12 and an implanted electrode 13 are provided inside the active trenches 11 via a gate insulating film 14. A bottom portion of the gate electrodes 12 is located closer to the second principal surface than the base layer 8. The implanted electrode 13 is positioned on the second principal surface 1b side of the gate electrodes 12, is insulated from the gate electrode 12 by the gate insulating film 14 and is electrically connected to the emitter electrode 5.

A buffer layer 15 of the first conductive type is provided on the second principal surface 1b side of the drift layer 2. Impurity concentration of the buffer layer 15 is higher than that of the drift layer 2. A collector layer 16 of the second conductive type is provided on the second principal surface 1b side of the buffer layer 15.

In the diode region 4, an anode layer 17 of the second conductive type is provided on the first principal surface 1a side of the drift layer 2. A diode contact layer 18 of the second conductive type is provided on the first principal surface side of the anode layer 17. Impurity concentration of the diode contact layer 18 is higher than that of the anode layer 17. A plurality of diode trenches 19 are provided from the first principal surface 1a of the semiconductor substrate 1 to the anode layer 17. A diode electrode 20 is provided inside the diode trenches 19 via a diode insulating film 21 and is electrically connected to the emitter electrode 5.

Also in the diode region 4, the buffer layer 15 of the first conductive type is provided on the second principal surface 1b side of the drift layer 2. A cathode layer 22 of the first conductive type is provided on the second principal surface 1b side of the buffer layer 15. In a depth in a direction from the first principal surface 1a of the semiconductor substrate 1 toward inside of the substrate, a depth of the anode layer 17 is deeper than a depth of the diode trenches 19.

A plurality of active trenches 11 and a plurality of diode trenches 19 are arranged in parallel to each other in plan view. The emitter layer 9 and the collector layer 10 extend in a stripe shape so as to be orthogonal to the active trenches 11 in plan view and are alternately arranged. The anode layer 17 and the diode contact layer 18 extend in a stripe shape so as to be orthogonal to the diode trenches 19 in plan view and are alternately arranged.

An interlayer dielectric film 23 is provided on the active trenches 11 and the diode trenches 19. The emitter electrode 5 is electrically connected to the emitter layer 9 and the contact layer 10 through an opening 23a of the interlayer dielectric film 23 and is electrically connected to the anode layer 17 and the diode contact layer 18 through an opening 23b of the interlayer dielectric film 23. The collector electrode 6 is electrically connected to the collector layer 16 and the cathode layer 22.

Upon recovery operation, the RC-IGBT discharges electrons accumulated in the diode region 4 from the second principal surface 1b side and discharges holes from the first principal surface 1a side to extend a depleted layer, thereby holding a power supply voltage between a collector and an emitter, and turns off a diode. In this event, if an electric field concentrates on bottom portions of the trenches, breakage is likely to occur upon recovery operation, that is, an RRSOA becomes narrow. Further, if holes are accumulated on the first principal surface 1a side of the semiconductor substrate 1, an electric field concentrates on a PN junction interface, and the RRSOA becomes narrow. Particularly, in an RC-IGBT having a split gate structure, a di/dt is great upon recovery, and thus, decrease in the RRSOA in the above mode is prominent. It is therefore necessary to relax an electric field on the bottom portions of the trenches or improve hole discharge efficiency.

In contrast, in the present embodiment, the depth of the anode layer 17 is made deeper than the depth of the diode trenches 19 in the diode region 4. By covering and protecting bottom portions of the diode trenches 19 with the anode layer 17, the electric field in the bottom portions of the diode trenches 19 can be relaxed. As a result of this, it is possible to improve the RRSOA in the RC-IGBT having a split gate structure.

### Second Embodiment

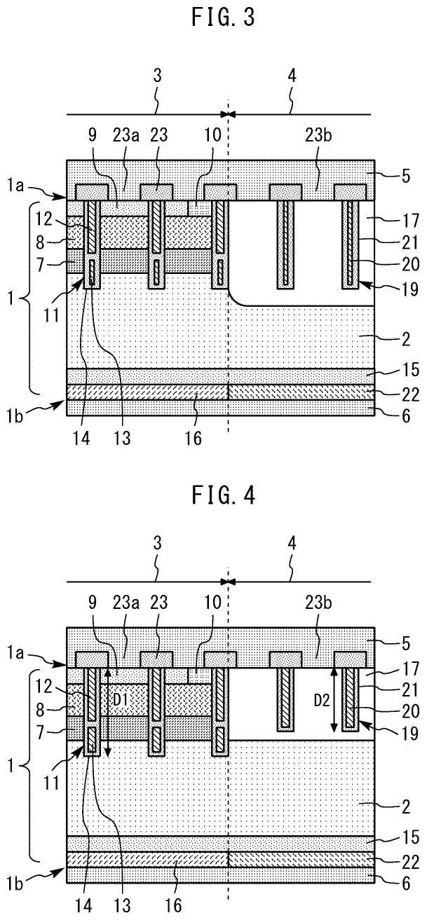

FIG. 3 is a cross-sectional view illustrating a semiconductor device according to a second embodiment. The gate insulating film 14 located on a side wall or a bottom portion of the implanted electrode 13 is thicker than the gate insulating film 14 located on a side wall of the gate electrode 12. This can protect the bottom portions of the active trenches 11, so that it is possible to improve gate reliability. Other configurations and effects are similar to those in the first embodiment.

### Third Embodiment

FIG. 4 is a cross-sectional view illustrating a semiconductor device according to a third embodiment. The anode layer 17 is formed by implanting ions of the second conductive type and then performing annealing at a high temperature for a long period, and a depth of the anode layer 17 is adjusted by an annealing temperature and an annealing period. In the present embodiment, the depth of the anode layer 17 is made shallower than the depth of the active trenches 11. This can shorten the annealing period of the anode layer 17, so that it is possible to reduce manufacturing cost. Further, a depth D2 of the diode trenches 19 is shallower than a depth D1 of the active trenches 11, and thus, the depth of the anode layer 17 is deeper than the depth of the diode trenches 19 in a similar manner to the first embodiment. Other configurations and effects are similar to those in the first embodiment.

### Fourth Embodiment

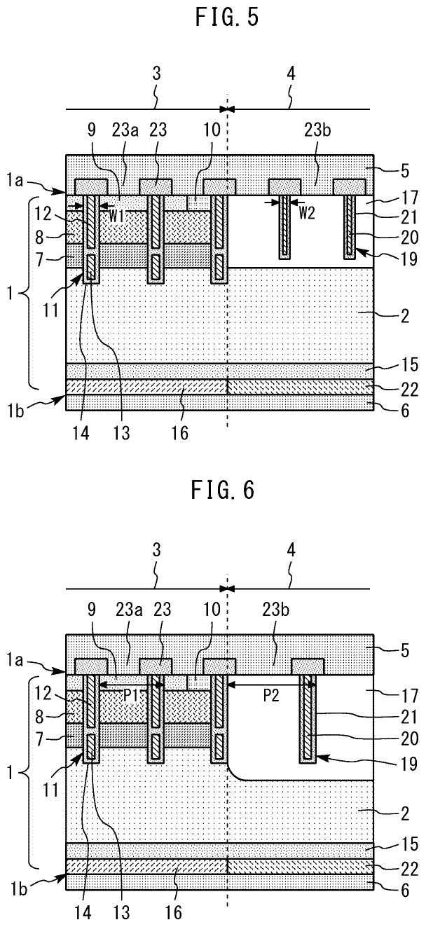

FIG. 5 is a cross-sectional view illustrating a semiconductor device according to a fourth embodiment. By a loading effect, a finished etching depth becomes shallow in a region where an opening width is narrow under the same etching condition. Thus, in the present embodiment, a width W2 of the diode trenches 19 is made narrower than a width W1 of the active trenches 11. By this means, in a case where the active trenches 11 and the diode trenches 19 are formed through the same etching process by utilizing the loading effect, the depth D2 of the diode trenches 19 can be made shallower than the depth D1 of the active trenches 11. It is therefore possible to reduce manufacturing cost. Other configurations and effects are similar to those in the third embodiment.

### Fifth Embodiment

FIG. 6 is a cross-sectional view illustrating a semiconductor device according to a fifth embodiment. A pitch P1 of the active trenches 11 is an interval between two adjacent active trenches 11. A pitch P2 of the diode trenches 19 is an interval between two adjacent diode trenches 19 or an interval between the active trench 11 and the diode trench 19 that are adjacent to each other. It is desirable that the pitch P1 of the active trenches 11 in the IGBT region 3 is designed to be narrow to reduce a conduction loss. Thus, in the present embodiment, the pitch P2 of the diode trenches 19 is made wider than the pitch P1 of the active trenches 11. This increases a contact area between the emitter electrode 5 and the anode layer 17 in the diode region 4 without changing the design of the IGBT region 3, increases hole discharge efficiency, and can thereby improve the RRSOA. Other configurations and effects are similar to those in the first embodiment.

### Sixth Embodiment

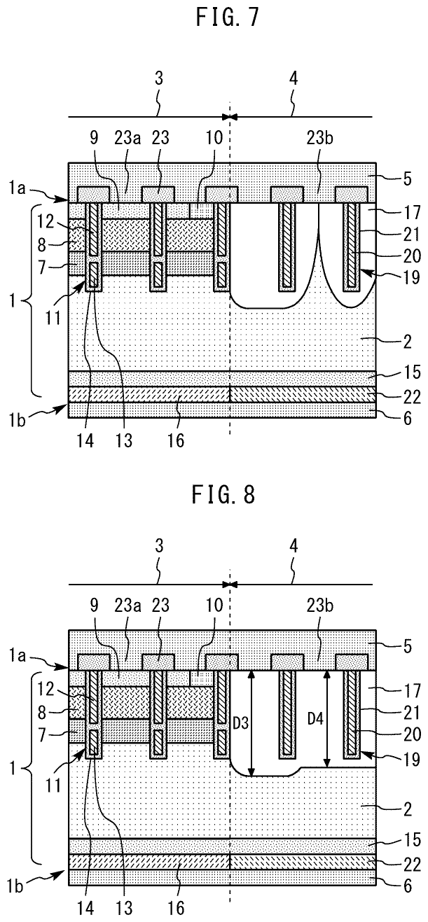

FIG. 7 is a cross-sectional view illustrating a semiconductor device according to a sixth embodiment. The anode layer 17 is the deepest at the bottom portions of the diode trenches 19, and the depth of the anode layer 17 is deeper than the depth of the diode trenches 19. The depth of the anode layer 17 is shallower than the depth of the diode trenches 19 in part of a region put between the diode trenches 19. In other words, the depth of the anode layer 17 in part of the region put between the diode trenches 19 is shallower than the depth of the anode layer 17 at the bottom portions of the diode trenches 19. This allows electrons to be discharged from the anode layer 17 that is formed shallow upon forward direction operation of the diode in which an electronic current flows from the collector electrode 6 to the emitter electrode 5. It is therefore possible to reduce a recovery loss by reducing carriers to be accumulated in the diode region 4. Other configurations and effects are similar to those in the first embodiment.

### Seventh Embodiment

FIG. 8 is a cross-sectional view illustrating a semiconductor device according to a seventh embodiment. There is a case where the RRSOA may deteriorate as a result of currents concentrating on a boundary between the IGBT region 3 and the diode region 4. Thus, in the present embodiment, a depth D3 of the anode layer 17 in a region adjacent to the IGBT region 3 is made deeper than a depth D4 of the anode layer 17 in a region not adjacent to the IGBT region 3. This can reduce a recovery loss by making a portion of the anode layer 17 far from the boundary shallow while improving the RRSOA by making a portion of the anode layer 17 near the boundary between the IGBT region 3 and the diode region 4 deep to relax an electric field at the trench bottom portions. Other configurations and effects are similar to those in the first embodiment.

### Eighth Embodiment

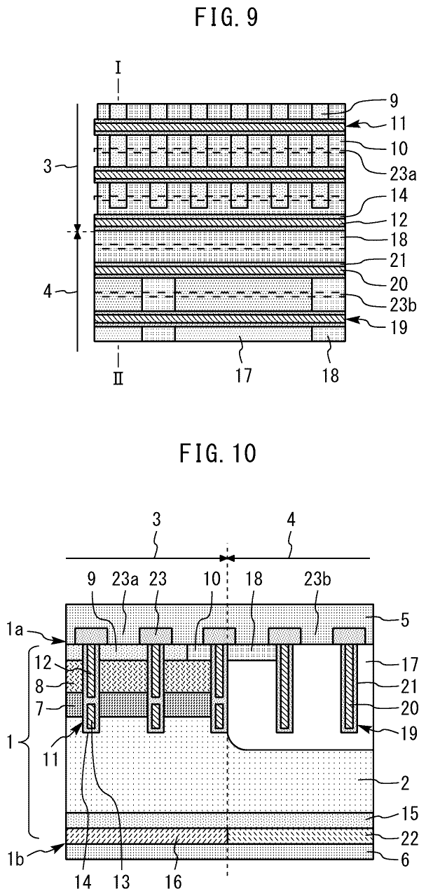

FIG. 9 is a plan view illustrating a semiconductor device according to an eighth embodiment. FIG. 10 is a cross-sectional view along I-II in FIG. 9. An area of the diode contact layer 18 formed in regions between the active trenches 11 and the diode trenches 19 in plan view is larger than an area of the diode contact layer 18 formed in a region between the diode trenches 19. This can adjust a recovery loss by the area of the diode contact layer formed in the region between the diode trenches 19 while improving the hole discharge efficiency at the boundary between the IGBT region 3 and the diode region 4 and improving the RRSOA. Other configurations and effects are similar to those in the first embodiment.

### Ninth Embodiment

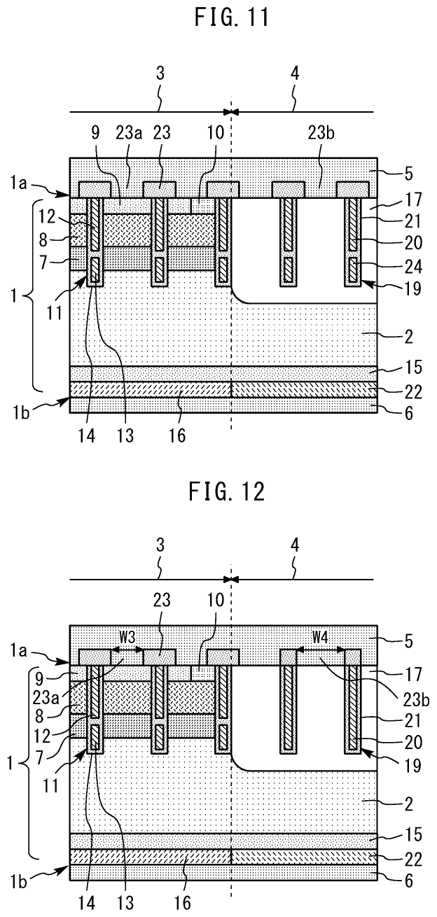

FIG. 11 is a cross-sectional view illustrating a semiconductor device according to a ninth embodiment. A diode implanted electrode 24 is provided inside the diode trenches 19 via the diode insulating film 21 and is positioned on the second principal surface side of the diode electrode 20. The diode implanted electrode 24 is insulated from the diode electrode 20 by the diode insulating film 21. A capacity ratio Cr/Ci of input capacity Ci and feedback capacity Cr can be adjusted by a potential of the diode electrode 20 or the diode implanted electrode 24. For example, compared to a case where both a potential of the diode electrode 20 and a potential of the diode implanted electrode 24 are an emitter potential, by setting the potential of the diode electrode 20 at an emitter potential and setting the potential of the diode implanted electrode 24 at a gate potential, it is possible to increase a capacity Cge between the gate and the emitter, increase Ci and reduce Cr/Ci. Other configurations and effects are similar to those in the first embodiment.

### Tenth Embodiment

FIG. 12 is a cross-sectional view illustrating a semiconductor device according to a tenth embodiment. A width of the opening 23b of the interlayer dielectric film 23 in the diode region 4 is wider than a width of the opening 23a of the interlayer dielectric film 23 in the IGBT region 3 in a direction orthogonal to the active trenches 11 and the diode trenches 19 in plan view. Thus, a contact width W4 between the emitter electrode 5 and the first principal surface 1a between the diode trenches 19 is wider than a contact width W3 between the emitter electrode 5 and the first principal surface 1a between the active trenches 11. By increasing the contact width W4 in the diode region 4 compared to the contact width W3 in the IGBT region 3 in this manner, it is possible to improve the hole discharge efficiency in the diode region 4 and improve the RRSOA without increasing short circuit failures between the active trenches 11 and the emitter electrode 5 in the IGBT region 3. Other configurations and effects are similar to those in the first embodiment.

### Eleventh Embodiment

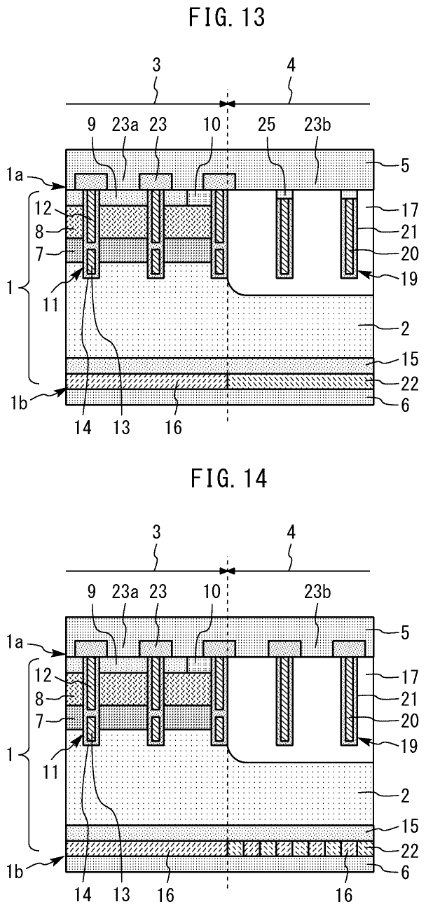

FIG. 13 is a cross-sectional view illustrating a semiconductor device according to an eleventh embodiment. An upper part of the diode electrode 20 is located closer to the second principal surface 1b than the first principal surface 1a of the semiconductor substrate 1. A recessed electrode 25 is provided between the diode electrode 20 and the emitter electrode 5 inside the diode trenches 19. The recessed electrode 25 is connected to the diode electrode 20 and the emitter electrode 5. A material of the recessed electrode 25 may be the same as a material of the emitter electrode 5. A side wall of the recessed electrode 25 is in contact with the semiconductor substrate 1. Thus, holes can be also discharged from the side wall of the recessed electrode 25, so that it is possible to improve the hole discharge efficiency and improve the RRSOA. Other configurations and effects are similar to those in the first embodiment.

### Twelfth Embodiment

FIG. 14 is a cross-sectional view illustrating a semiconductor device according to a twelfth embodiment. The collector layer 16 of the p type and the cathode layer 22 of the n type are alternately arranged on the second principal surface 1b side of the drift layer 2 in the diode region 4. This can reduce electron injection efficiency from the second principal surface 1b side and reduce a recovery loss. Other configurations and effects are similar to those in the first embodiment.

### Thirteenth Embodiment

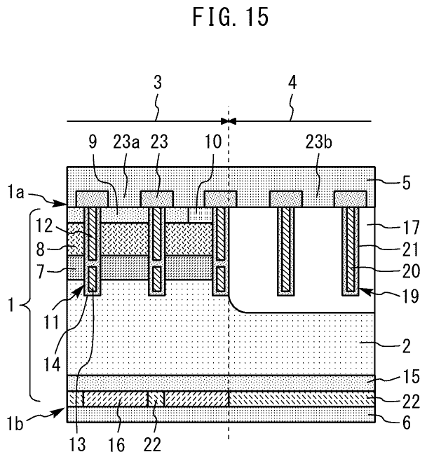

FIG. 15 is a cross-sectional view illustrating a semiconductor device according to a thirteenth embodiment. The collector layer 16 of the p type and the cathode layer 22 of the n type are alternately arranged on the second principal surface 1b side of the drift layer 2 in the IGBT region 3. This can reduce hole injection efficiency from the second principal surface 1b side and reduce a turn off loss. Other configurations and effects are similar to those in the first embodiment.

The semiconductor substrate 1 is not limited to a substrate formed of silicon, but instead may be formed of a wide-bandgap semiconductor having a bandgap wider than that of silicon. The wide-bandgap semiconductor is, for example, a silicon carbide, a gallium-nitride-based material, or diamond. A semiconductor chip formed of such a wide-bandgap semiconductor has a high voltage resistance and a high allowable current density, and thus can be miniaturized. The use of such a miniaturized semiconductor chip enables the miniaturization and high integration of the semiconductor device in which the semiconductor chip is incorporated. Further, since the semiconductor chip has a high heat resistance, a radiation fin of a heatsink can be miniaturized and a water-cooled part can be air-cooled, which leads to further miniaturization of the semiconductor device. Further, since the semiconductor chip has a low power loss and a high efficiency, a highly efficient semiconductor device can be achieved.

While preferred embodiments, and the like, have been described above, the present disclosure is not limited to the above-described embodiments, and the like, and various modifications and replacement can be made to the above-described embodiments, and the like, without deviating from the scope recited in the claims. The present disclosure can be applied without limitation in a withstand voltage class, an FZ substrate, an MCZ substrate, an epitaxial substrate, and the like. Different embodiments can be combined, and a configuration of each embodiment can be partially applied to a certain region. Further, while description has been provided using an example of a case where the IGBT region 3 is adjacent to the diode region 4, a boundary region (a region having a diode structure on the first principal surface side and having a collector layer on the second principal surface side) may be provided between the IGBT region 3 and the diode region 4.

Aspects of the present disclosure will be collectively described as supplementary notes.

### (Supplementary Note 1)

A semiconductor device comprising:
a semiconductor substrate including a drift layer of a first conductive type between a first principal surface and a second principal surface opposed to each other;
an IGBT region and a diode region provided on the semiconductor substrate; and
an emitter electrode provided on the first principal surface of the semiconductor substrate,
wherein the IGBT region includes
a carrier accumulation layer of the first conductive type provided on the first principal surface side of the drift layer,
a base layer of a second conductive type provided on the first principal surface side of the carrier accumulation layer,
an emitter layer of the first conductive type and a contact layer of the second conductive type provided on the first principal surface side of the base layer,
a plurality of active trenches penetrating through the base layer and the emitter layer from the first principal surface,
a gate electrode provided inside the active trenches via a gate insulating film,
an implanted electrode provided inside the active trenches via the gate insulating film and positioned on the second principal surface side of the gate electrode, and
a collector layer of the second conductive type provided on the second principal surface side of the drift layer,
wherein the diode region includes
an anode layer of the second conductive type provided on the first principal surface side of the drift layer,
a plurality of diode trenches provided from the first principal surface to the anode layer;
a diode electrode provided inside the diode trenches via a diode insulating film, and
a cathode layer of the first conductive type provided on the second principal surface side of the drift layer,
wherein a depth of the anode layer is deeper than a depth of the diode trenches.

### (Supplementary Note 2)

The semiconductor device according to Supplementary Note 1, wherein the implanted electrode is insulated from the gate electrode and is electrically connected to the emitter electrode, and
the diode electrode is electrically connected to the emitter electrode.

### (Supplementary Note 3)

The semiconductor device according to Supplementary Note 1 or 2, wherein the gate insulating film located on a side wall or a bottom portion of the implanted electrode is thicker than the gate insulating film located on a side wall of the gate electrode.

### (Supplementary Note 4)

The semiconductor device according to any one of Supplementary Notes 1 to 3, wherein a depth of the anode layer is shallower than a depth of the active trench.

### (Supplementary Note 5)

The semiconductor device according to Supplementary Note 4, wherein a width of the diode trench is narrower than a width of the active trench, and
a depth of the diode trench is shallower than a depth of the active trench.

### (Supplementary Note 6)

The semiconductor device according to any one of Supplementary Notes 1 to 5, wherein a pitch of the plurality of diode trenches is wider than a pitch of the plurality of active trenches.

### (Supplementary Note 7)

The semiconductor device according to any one of Supplementary Notes 1 to 6, wherein a depth of the anode layer in part of a region put between the diode trenches is shallower than a depth of the anode layer at bottom portions of the diode trenches.

### (Supplementary Note 8)

The semiconductor device according to any one of Supplementary Notes 1 to 7, wherein a depth of the anode layer in a region adjacent to the IGBT region is deeper than a depth of the anode layer in a region not adjacent to the IGBT region.

### (Supplementary Note 9)

The semiconductor device according to any one of Supplementary Notes 1 to 8, wherein the diode region includes a diode contact layer of the second conductive type provided on the first principal surface side of the anode layer and having higher impurity concentration than that of the anode layer, and
an area of the diode contact layer formed in a region between the active trench and the diode trench in plan view is larger than an area of the diode contact layer formed in a region between the diode trenches.

### (Supplementary Note 10)

The semiconductor device according to any one of Supplementary Notes 1 to 9, wherein the diode region includes a diode implanted electrode provided inside the diode trenches via the diode insulating film, positioned on the second principal surface side of the diode electrode and insulated from the diode electrode.

### (Supplementary Note 11)

The semiconductor device according to any one of Supplementary Notes 1 to 10, wherein a contact width between the emitter electrode and the first principal surface between the diode trenches is wider than a contact width between the emitter electrode and the first principal surface between the active trenches.

### (Supplementary Note 12)

The semiconductor device according to any one of Supplementary Notes 1 to 11, wherein the diode region includes a recessed electrode provided between the diode electrode and the emitter electrode inside the diode trench and a side wall of the recessed electrode is in contact with the semiconductor substrate.

### (Supplementary Note 13)

The semiconductor device according to any one of Supplementary Notes 1 to 12, wherein the collector layer and the cathode layer are alternately arranged on the second principal surface side of the drift layer in the diode region.

### (Supplementary Note 14)

The semiconductor device according to any one of Supplementary Notes 1 to 13, wherein the collector layer and the cathode layer are alternately arranged on the second principal surface side of the drift layer in the IGBT region.

### (Supplementary Note 15)

The semiconductor device according to any one of Supplementary Notes 1 to 14, wherein the semiconductor substrate is formed of a wide-bandgap semiconductor.

Obviously many modifications and variations of the present disclosure are possible in the light of the above teachings. It is therefore to be understood that within the scope of the appended claims the invention may be practiced otherwise than as specifically described.

The entire disclosure of Japanese Patent Application No. 2022-182542, filed on Nov. 15, 2022 including specification, claims, drawings and summary, on which the convention priority of the present application is based, is incorporated herein by reference in its entirety.

1. A semiconductor device comprising:
a semiconductor substrate including a drift layer of a first conductive type between a first principal surface and a second principal surface opposed to each other;
an IGBT region and a diode region provided on the semiconductor substrate; and
an emitter electrode provided on the first principal surface of the semiconductor substrate,
wherein the IGBT region includes
a carrier accumulation layer of the first conductive type provided on the first principal surface side of the drift layer,
a base layer of a second conductive type provided on the first principal surface side of the carrier accumulation layer,
an emitter layer of the first conductive type and a contact layer of the second conductive type provided on the first principal surface side of the base layer,
a plurality of active trenches penetrating through the base layer and the emitter layer from the first principal surface,
a gate electrode provided inside the active trenches via a gate insulating film,
an implanted electrode provided inside the active trenches via the gate insulating film and positioned on the second principal surface side of the gate electrode, and
a collector layer of the second conductive type provided on the second principal surface side of the drift layer,
wherein the diode region includes
an anode layer of the second conductive type provided on the first principal surface side of the drift layer,
a plurality of diode trenches provided from the first principal surface to the anode layer,
a diode electrode provided inside the diode trenches via a diode insulating film, and
a cathode layer of the first conductive type provided on the second principal surface side of the drift layer,
wherein a depth of the anode layer is deeper than a depth of the diode trenches.

2. The semiconductor device according to claim 1, wherein the implanted electrode is insulated from the gate electrode and is electrically connected to the emitter electrode, and
the diode electrode is electrically connected to the emitter electrode.

3. The semiconductor device according to claim 1, wherein the gate insulating film located on a side wall or a bottom portion of the implanted electrode is thicker than the gate insulating film located on a side wall of the gate electrode.

4. The semiconductor device according to claim 1, wherein a depth of the anode layer is shallower than a depth of the active trench.

5. The semiconductor device according to claim 4, wherein a width of the diode trench is narrower than a width of the active trench, and
a depth of the diode trench is shallower than a depth of the active trench.

6. The semiconductor device according to claim 1, wherein a pitch of the plurality of diode trenches is wider than a pitch of the plurality of active trenches.

7. The semiconductor device according to claim 1, wherein a depth of the anode layer in part of a region put between the diode trenches is shallower than a depth of the anode layer at bottom portions of the diode trenches.

8. The semiconductor device according to claim 1, wherein a depth of the anode layer in a region adjacent to the IGBT region is deeper than a depth of the anode layer in a region not adjacent to the IGBT region.

9. The semiconductor device according to claim 1, wherein the diode region includes a diode contact layer of the second conductive type provided on the first principal surface side of the anode layer and having higher impurity concentration than that of the anode layer, and
an area of the diode contact layer formed in a region between the active trench and the diode trench in plan view is larger than an area of the diode contact layer formed in a region between the diode trenches.

10. The semiconductor device according to claim 1, wherein the diode region includes a diode implanted electrode provided inside the diode trenches via the diode insulating film, positioned on the second principal surface side of the diode electrode and insulated from the diode electrode.

11. The semiconductor device according to claim 1, wherein a contact width between the emitter electrode and the first principal surface between the diode trenches is wider than a contact width between the emitter electrode and the first principal surface between the active trenches.

12. The semiconductor device according to claim 1, wherein the diode region includes a recessed electrode provided between the diode electrode and the emitter electrode inside the diode trench and a side wall of the recessed electrode is in contact with the semiconductor substrate.

13. The semiconductor device according to claim 1, wherein the collector layer and the cathode layer are alternately arranged on the second principal surface side of the drift layer in the diode region.

14. The semiconductor device according to claim 1, wherein the collector layer and the cathode layer are alternately arranged on the second principal surface side of the drift layer in the IGBT region.

15. The semiconductor device according to claim 1, wherein the semiconductor substrate is formed of a wide-bandgap semiconductor.
